(19) United States
(12) Patent Application Publication
(10) Pub. No.: US 2025/0203886 A1
(43) Pub. Date: Jun. 19, 2025

(54) THIN FILM RESISTORS AND METHODS OF FORMING THE SAME

(71) Applicant: Taiwan Semiconductor Manufacturing Company, Ltd., Hsinchu (TW)

(72) Inventors: Chun-Tsung KUO, Tainan City (TW); Hung-Wen HSU, Tainan City (TW); Jiech-Fun LU, Taiwan (TW)

(21) Appl. No.: 18/405,450

(22) Filed: Jan. 5, 2024

Related U.S. Application Data
(60) Provisional application No. 63/611,621, filed on Dec. 18, 2023.

(51) Int. Cl. H01C 17/075; H01L 23/522

(52) U.S. Cl. CPC H10D 1/474; H01C 17/075; H01L 23/5228

(57) ABSTRACT

Some implementations described herein provide a semiconductor structure. The semiconductor structure includes a thin film resistor (TFR) with a taper profile. The semiconductor structure further includes a first contact physically contacting a first portion of the TFR. The semiconductor structure includes a second contact physically contacting a second portion of the TFR. The semiconductor structure further includes an oxide layer, over the second dielectric layer and surrounding the first contact and the second contact, and an inter-metal dielectric (IMD) layer over the oxide layer. The IMD layer is substantially free of voids and surrounds a first metal plug physically contacting the first contact and a second metal plug physically contacting the second contact.

### CROSS-REFERENCE TO RELATED APPLICATION

This patent application claims priority to Provisional Patent Application No. 63/611,621, filed on Dec. 18, 2023, and entitled “THIN FILM RESISTORS AND METHODS OF FORMING THE SAME.” The disclosure of the prior application is considered part of and is incorporated by reference into this patent application.

### BACKGROUND

Semiconductor-based integrated circuits may include a wide range of semiconductor devices. These semiconductor devices may include active semiconductor devices and/or passive semiconductor devices. Active semiconductor devices may include transistors and other semiconductor devices that operate using a power source. Passive semiconductor devices include inductors, capacitors, resistors, and/or other semiconductor devices that can operate without a power source. Resistors are widely used in many applications, such as resistor-capacitor circuits, power drivers, power amplifiers, and/or radio frequency applications, among other examples.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIG. 2 is a diagram of an example semiconductor structure described herein.

FIGS. 3A-3B are diagrams of an example semiconductor structure described herein.

FIGS. 4A-4N are diagrams of an example implementation described herein.

FIGS. 5A-5C are diagrams of example semiconductor layouts described herein.

FIG. 6 is a diagram of example components of one or more devices of FIG. 1 described herein.

FIG. 7 is a flowchart of an example process associated with forming a thin film resistor described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, a resistor, such as a thin film resistor (TFR), may be formed in an interconnect region of a semiconductor device. A resistive layer of the TFR may be formed of silicon chromium (SiCr). Contact structures for the TFR may be formed of titanium nitride (TiN) and over the resistive layer. Additionally, capping layers may be formed of a silicon oxynitride (SiON) and formed over the contact structures. Forming the contact structures may include depositing a layer of conductive material (e.g., TiN) over the resistive layer and removing portions of the layer of conductive material by etching. Remaining portions of the layer of conductive material may function as the contact structures.

During formation of the contract structures, lateral etching of the contact structures may occur, such that widths of the contact structures are reduced. Lateral etching results in overhang of the capping layers, such that the capping layers extend laterally outward past the contact structures. Because of the overhang, voids and/or seams may form when a dielectric layer (e.g., an inter-metal dielectric (IMD)) is formed around the contact structures. These voids and/or seams may reduce the structural integrity of the interconnect region, and may cause portions of the interconnect region to collapse and fail. Additionally, during chemical mechanical planarization (CMP), etchant may leak through the seams and damage the resistive layer. Therefore, the semiconductor device may experience reduced functionality and/or performance caused by non-functional components in the interconnect region. Moreover, the voids and/or seams may result in reduced semiconductor device yield in that semiconductor devices with non-functional components in the interconnect region may be scrapped.

Some implementations described herein provide techniques and apparatuses for forming a TFR with a taper profile, which allows for patterning of contact structures after deposition of a protective dielectric layer. Therefore, there is no lateral etching of the contact structures and thus no overhang to result in voids and/or seams when a dielectric layer (e.g., an IMD) is formed around the contact structures. As a result, a process window for the TFR is improved because the contact structures are not reduced by lateral etching. Furthermore, with no lateral etching of the contact structures, voids and/or seams are reduced (or even eliminated) when a dielectric layer (e.g., an IMD) is formed around the contact structures. Fewer voids and/or seams improves the structural integrity of the interconnect region and prevents damage to the resistive layer during CMP. Therefore, measurement accuracy for the TFR is increased. Moreover, fewer voids and/or seams result in increased semiconductor device yield in that fewer semiconductor devices are formed with non-functional components in the interconnect region and thus fewer semiconductor devices are scrapped.

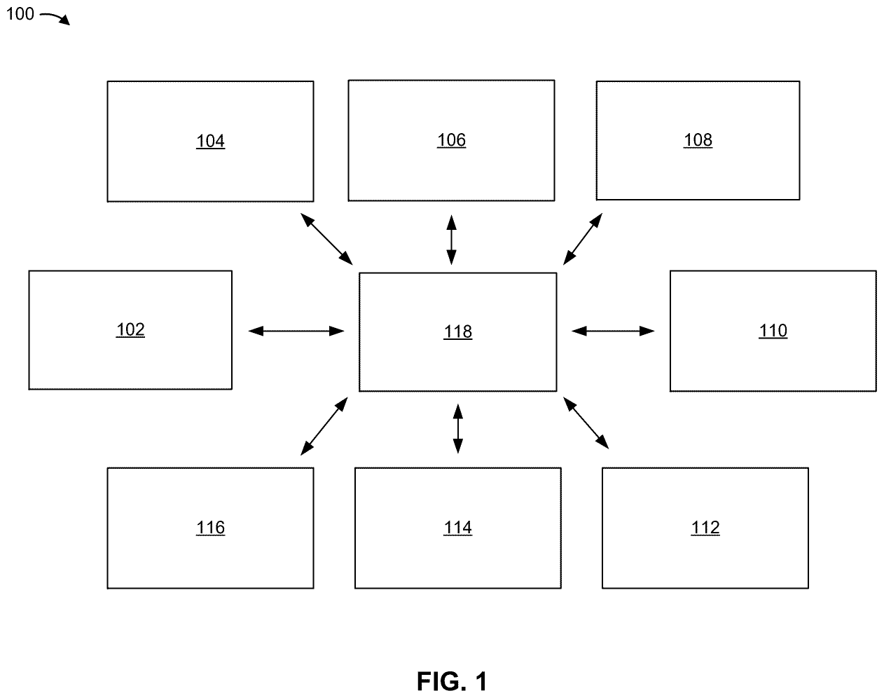

FIG. 1 is a diagram of an example environment 100 in which systems and/or methods described herein may be implemented. As shown in FIG. 1, environment 100 may include a plurality of semiconductor processing tools 102-116 and a wafer/die transport tool 118. The plurality of semiconductor processing tools 102-116 may include a deposition tool 102, an exposure tool 104, a developer tool 106, an etch tool 108, a planarization tool 110, a plating tool 112, a photoresist removal tool 114, an annealing tool 116, and/or another semiconductor processing tool. The tools included in the example environment 100 may be included in a semiconductor clean room, a semiconductor foundry, a semiconductor processing and/or manufacturing facility, or another location.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a low pressure CVD (LPCVD) tool, a high-density plasma CVD (HDP-CVD) tool, a sub-atmospheric CVD (SACVD) tool, an atomic layer deposition (ALD) tool, a plasma-enhanced atomic layer deposition (PEALD) tool, an epitaxy tool, or another type of CVD tool. In some implementations, the deposition tool 102 includes a physical vapor deposition (PVD) tool, such as a sputtering tool or another type of PVD tool. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a CMP tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The photoresist removal tool 114 is a semiconductor processing tool that is capable of removing remaining portions of a photoresist layer from a substrate after the etch tool 108 removes portions of the substrate. For example, the photoresist removal tool 114 may use a chemical stripper and/or another technique to remove a photoresist layer from a substrate.

The annealing tool 116 is a semiconductor processing tool that includes a semiconductor processing chamber and one or more devices capable of heating a semiconductor substrate or semiconductor device. For example, the annealing tool 116 may include a rapid thermal annealing (RTA) tool or another type of annealing tool that is capable of heating a semiconductor substrate to cause a reaction between two or more materials or gasses, to cause a material to decompose. As another example, the annealing tool 116 may be configured to heat (e.g., raise or elevate the temperature of) a structure or a layer (or portions thereof) to re-flow the structure or the layer, or to crystallize the structure or the layer, to remove defects such as voids or seams. As another example, the annealing tool 116 may be configured to heat (e.g., raise or elevate the temperature of) a layer (or portions thereof) to enable bonding of two or more semiconductor devices.

The wafer/die transport tool 118 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 118 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations).

In some implementations, one or more of the semiconductor processing tools 102-116 and/or the wafer/die transport tool 118 may perform one or more semiconductor processing operations described herein. For example, one or more of the semiconductor processing tools 102-116 and/or the wafer/die transport tool 118 may pattern a semiconductor stack into a taper profile, where the semiconductor stack includes a first dielectric layer, a TFR, and a second dielectric layer and is over a supporting dielectric layer; form an oxide layer over the second dielectric layer; form a first contact and a second contact, within the oxide layer, that physically contact the TFR; form an IMD layer over the oxide layer; form a third recess and a fourth recess in the IMD layer; and/or form, within the IMD layer, a first metal plug that physically contacts the first contact and a second metal plug that physically contacts the second contact. In another example, one or more of the semiconductor processing tools 102-116 and/or the wafer/die transport tool 118 may form a first photoresist layer over a semiconductor stack including a first dielectric layer, a TFR, and a second dielectric layer; pattern the semiconductor stack into a taper profile using the first photoresist layer; form an oxide layer over the second dielectric layer; form a second photoresist layer over the oxide layer; form a first recess and a second recess in the oxide layer using the second photoresist layer; expand the first recess and the second recess to expose a portion of the TFR; form a first contact in the first recess and a second contact in the second recess; form an IMD layer over the oxide layer; form a third recess and a fourth recess in the IMD layer; and/or form a first metal plug in the third recess and a second metal plug in the fourth recess.

The number and arrangement of tools shown in FIG. 1 are provided as one or more examples. In practice, there may be additional tools, fewer tools, different tools, or differently arranged tools than those shown in FIG. 1. Furthermore, two or more tools shown in FIG. 1 may be implemented within a single tool, or a single tool shown in FIG. 1 may be implemented as multiple, distributed tools. Additionally, or alternatively, a set of tools (e.g., one or more tools) of environment 100 may perform one or more functions described as being performed by another set of tools of environment 100.

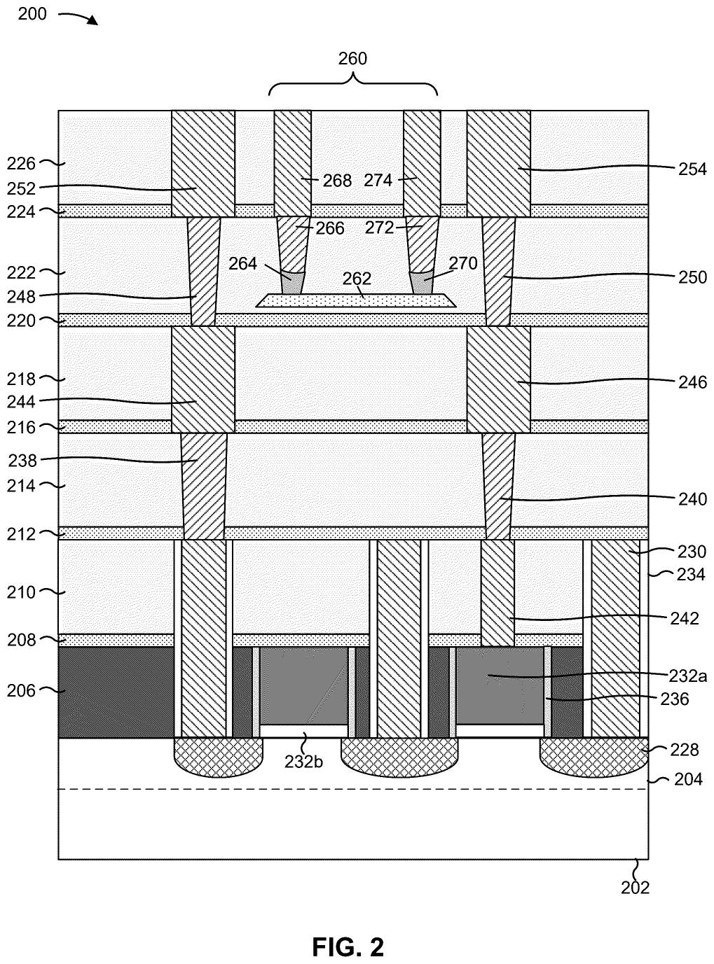

FIG. 2 is a diagram of a portion of an example semiconductor device 200 described herein. The semiconductor device 200 includes an example of a semiconductor device, such as a semiconductor memory device (e.g., a static random access memory (SRAM), a dynamic random access memory (DRAM)), a semiconductor logic device, a processor, an input/output device, or another type of semiconductor device that includes one or more transistors.

The semiconductor device 200 includes a substrate 202 (e.g., a silicon substrate) and one or more fin structures 204. The semiconductor device 200 further includes one or more stacked layers, including a dielectric layer 206, an etch stop layer (ESL) 208, a dielectric layer 210, an ESL 212, a dielectric layer 214, an ESL 216, a dielectric layer 218, an ESL 220, a dielectric layer 222, an ESL 224, and a dielectric layer 226, among other examples. The dielectric layers 206, 210, 214, 218, 222, and 226 are included to electrically isolate various structures of the semiconductor device 200. The dielectric layers 206, 210, 214, 218, 222, and 226 include a silicon nitride (SiNₓ), an oxide (e.g., a silicon oxide (SiOₓ) and/or another oxide material), and/or another type of dielectric material. The ESLs 208, 212, 216, 220, and 224 include a layer of material that is configured to permit various portions of the semiconductor device 200 (or the layers included therein) to be selectively etched or protected from etching to form one or more of the structures included in the semiconductor device 200. An “ESL” may include a single layer of material or a multi-layer stack of different materials selected to function as a single ESL.

As further shown in FIG. 2, the semiconductor device 200 includes a plurality of epitaxial (epi) regions 228 that are grown and/or otherwise formed on and/or around portions of the fin structure 204. The epitaxial regions 228 are formed by epitaxial growth. In some implementations, the epitaxial regions 228 are formed in recessed portions in the fin structure 204. The recessed portions may be formed by strained source drain (SSD) etching of the fin structure 204 and/or another type etching operation. The epitaxial regions 228 function as source/drain regions of the transistors included in the semiconductor device 200. Source/drain region(s) may refer to a source or a drain, individually or collectively, dependent upon the context.

The epitaxial regions 228 are electrically connected to metal source or drain contacts 230 of the transistors included in the semiconductor device 200. The metal source or drain contacts 230 include cobalt (Co), ruthenium (Ru), and/or another conductive or metal material. The transistors further include gates 232a, which are formed of a polysilicon material, a metal (e.g., tungsten (W) or another metal), and/or another type of conductive material. Additionally, the transistors may further include gate dielectric layers 232b, which may be formed of a same material as the gates 232a. The metal source or drain contacts 230 and the gate structures 232 are electrically isolated by one or more sidewall spacers, including spacers 234 in each side of the metal source or drain contacts 230 and spacers 236 on each side of the gate structures 232. The spacers 234 and 236 include a silicon oxide (SiOₓ), a silicon nitride (SiₓN_{y}), a silicon oxy carbide (SiOC), a silicon oxycarbonitride (SiOCN), and/or another suitable material. In some implementations, the spacers 234 are omitted from the sidewalls of the source or drain contacts 230.

As further shown in FIG. 2, the metal source or drain contacts 230 and the gate structures 232 are electrically connected to one or more types of interconnects. The interconnects electrically connect the transistors of the semiconductor device 200 and/or electrically connect the transistors to other areas and/or components of the semiconductor device 200. In some implementations, the interconnects electrically connect the transistors to an interconnect region of the semiconductor device 200.

The metal source or drain contacts 230 are electrically connected to source or drain interconnects 238 (e.g., also referred to as “source/drain vias”). One or more of the gate structures 232 are electrically connected to gate interconnects 240 (e.g., also referred to as “gate vias”). The interconnects 238 and 240 include a conductive material such as tungsten, cobalt, ruthenium, copper, and/or another type of conductive material. In some implementations, the gate structures 232 are electrically connected to the gate interconnects 240 by gate contacts 242 to reduce contact resistance between the gate structures 232 and the gate interconnects 240. The gate contacts 242 include tungsten (W), cobalt (Co), ruthenium (Ru), titanium (Ti), aluminum (Al), copper (Cu) or gold (Au), among other examples of conductive materials.

As further shown in FIG. 2, the interconnects 238 and 240 are electrically connected to a plurality of conductive layers, each including one or more metal plugs and/or vias. As an example, the interconnects 238 and 240 may be electrically connected to an M0 metallization layer that includes conductive structures 244 and 246. The M0 metallization layer is electrically connected to a V0 via layer that includes vias 248 and 250. The V0 via layer is electrically connected to an M1 metallization that includes conductive structures 252 and 254. In some implementations, the conductive layers of the semiconductor device 200 includes additional metallization layers, metal plugs, and/or vias that connect the semiconductor device 200 to a package.

As further shown in FIG. 2, the semiconductor device 200 may include one or more devices and/or structures in the interconnect region of the semiconductor device 200. For example, the semiconductor device 200 may include one or more semiconductor resistor structures, such as resistor structure 260, in the interconnect region of the semiconductor device 200. As shown in FIG. 2, the resistor structure 260 may be included in dielectric layers 222 and 226 in the interconnect region of the semiconductor device 200. Other examples may additionally or alternatively include the resistor structure 260 in one or more of the dielectric layers 210, 214, or 218.

The resistor structure 260 includes a TFR 262. The TFR 262 may include one or more materials configured to provide electrical resistance. In some implementations, the TFR 262 includes silicon chromium (SiCr) resistive material and/or nickel chromium (NiCr) resistive material. Chromium-based resistive material may provide a reduced temperature coefficient of resistance (TCR) relative to other types of resistive material (e.g., polysilicon resistive materials). The reduced TCR may result in reduced changes in resistance in the resistor structure 260, relative to a resistor structure that includes polysilicon resistive materials, due to heat.

The resistor structure 260 includes a contact 264 physically contacting one end of the TFR 262. The contact 264 physically contacts a metal plug 266 that is further connected to additional structures (e.g., metal plug 268). Similarly, the resistor structure includes a contact 270 physically contacting an opposite end of the TFR 262. The contact 270 physically contacts a metal plug 272 that is further connected to additional structures (e.g., metal plug 274). The contacts 264 and 270 are electrically connected with the TFR 262 and provide an input to, and an output from, the TFR 262. Thus, the contacts 264 and 270 function as the terminals of the resistor structure 260. The contacts 264 and 270 may each include one or more electrically conductive materials, such as titanium nitride (TiN) and/or tantalum nitride (TaN), a ceramic material, a metal material, a metal alloy, and/or another electrically conductive material, among other examples.

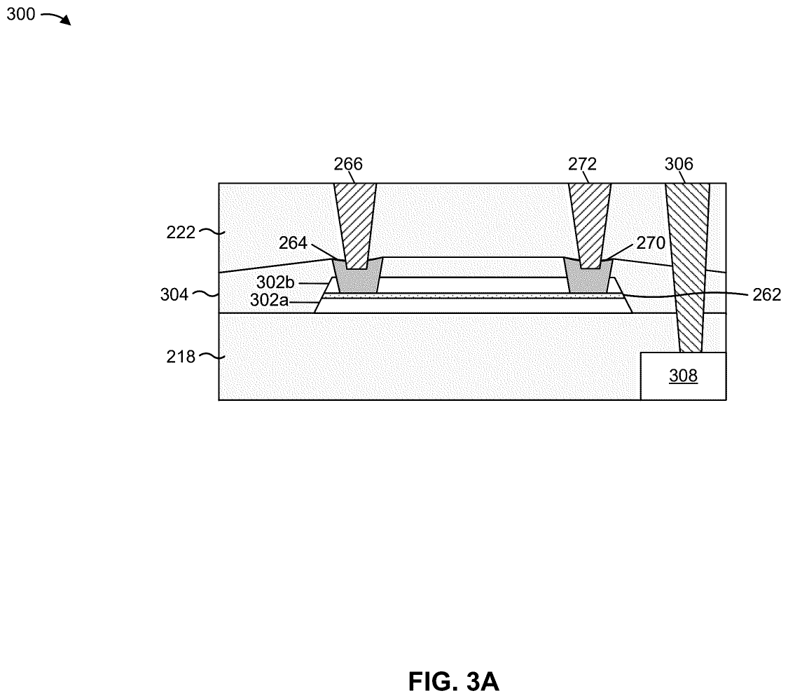

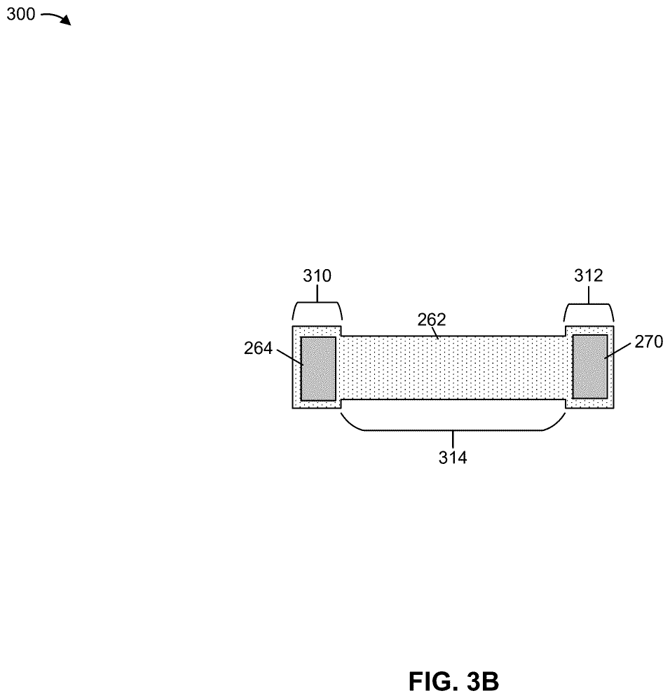

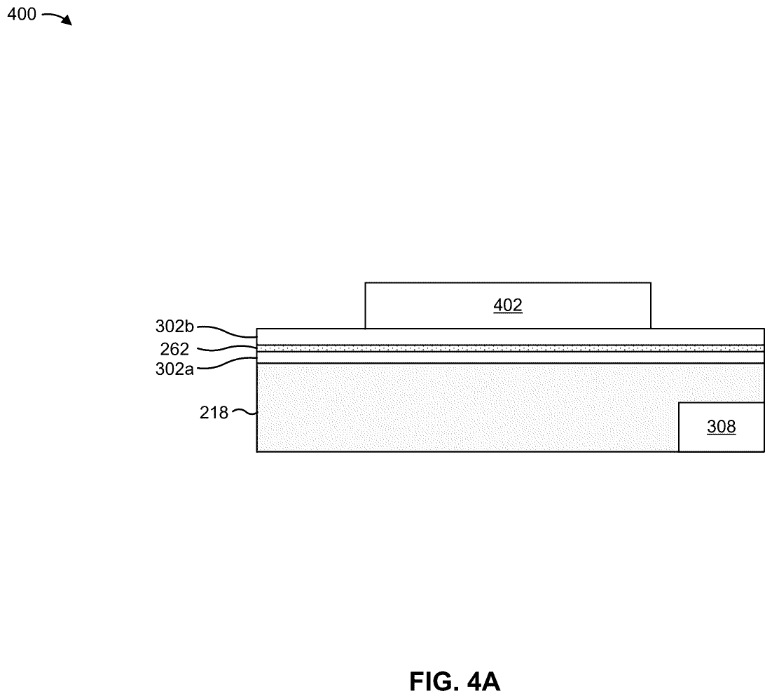

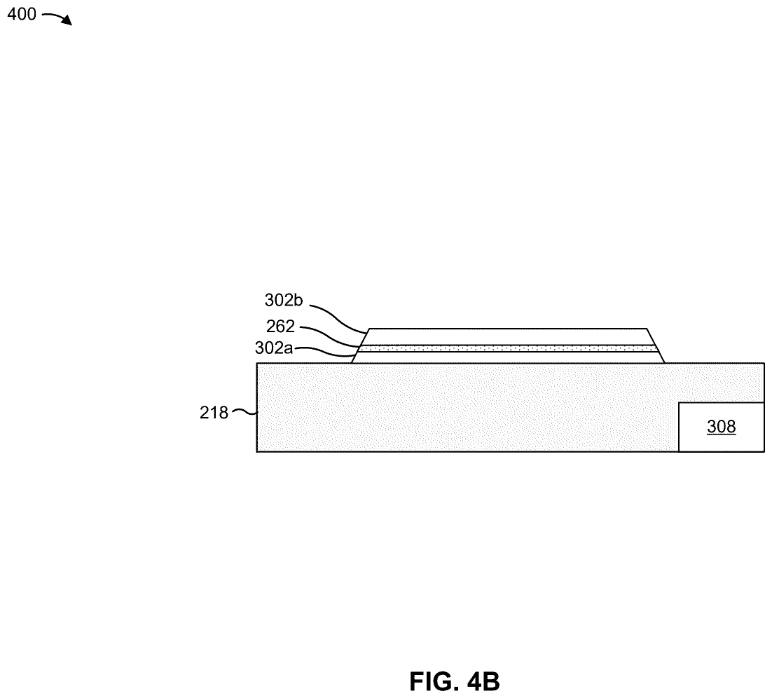

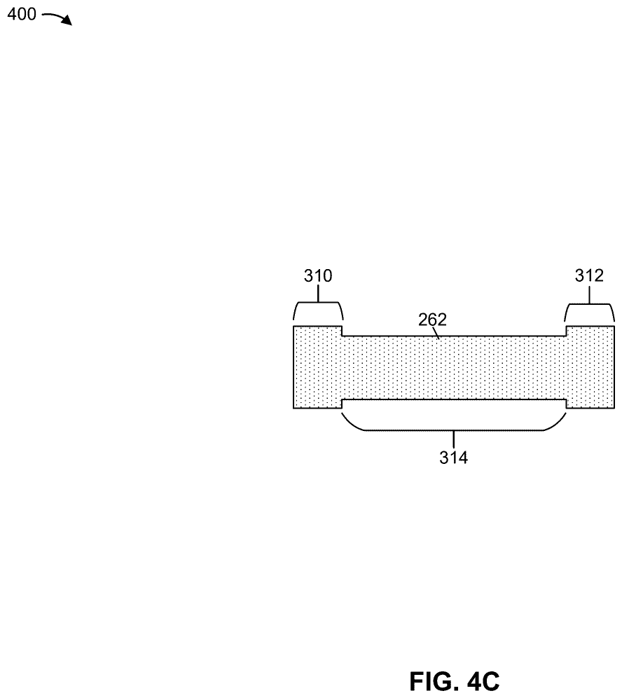

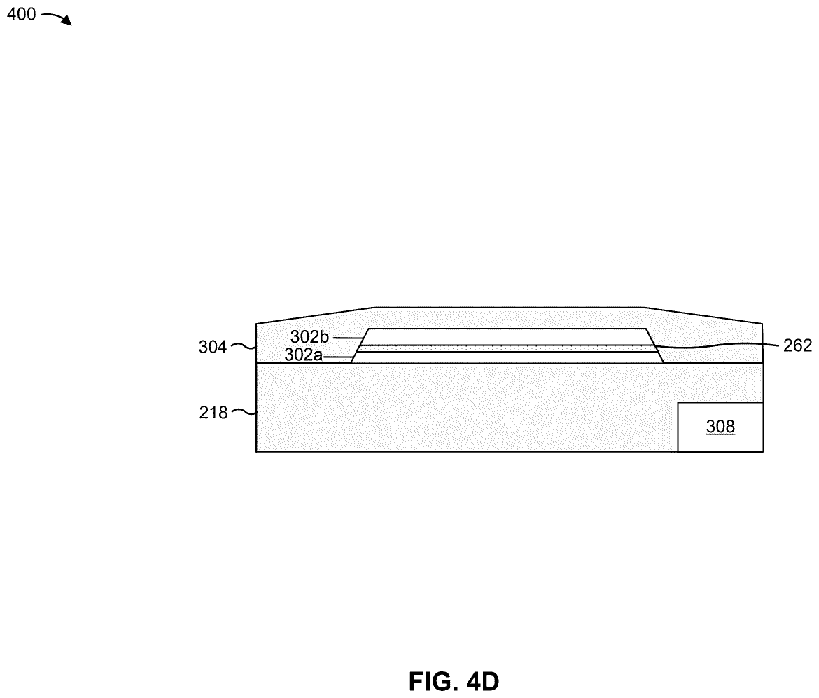

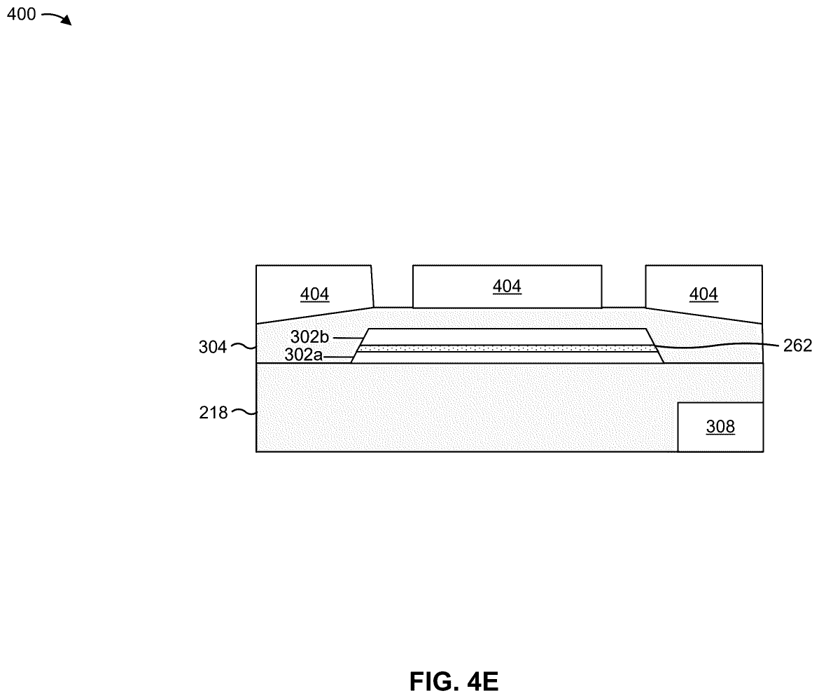

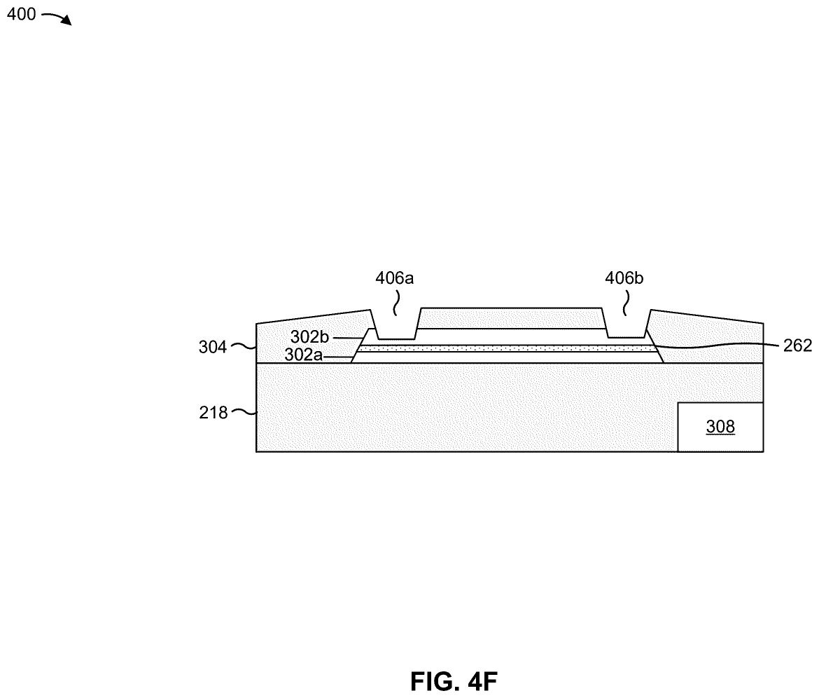

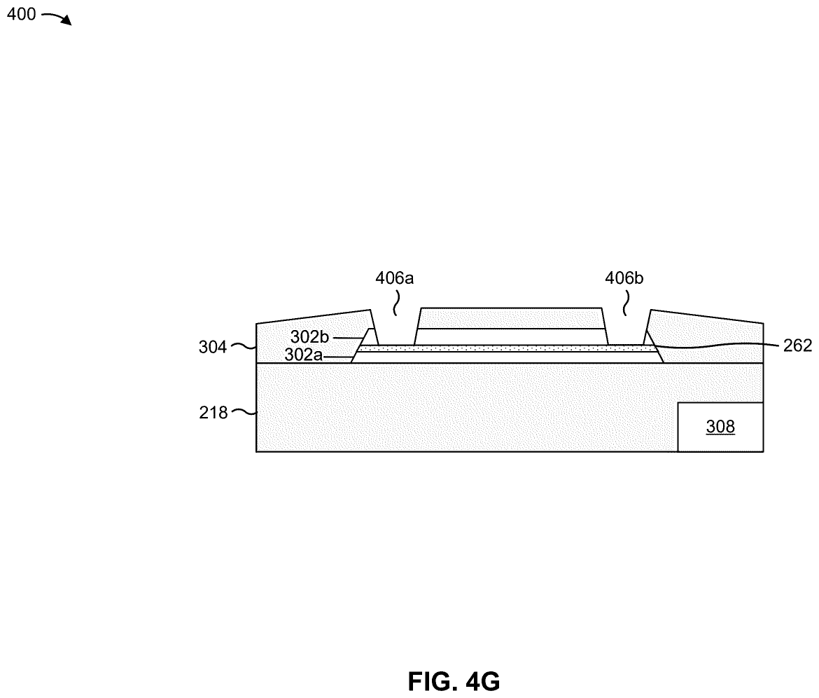

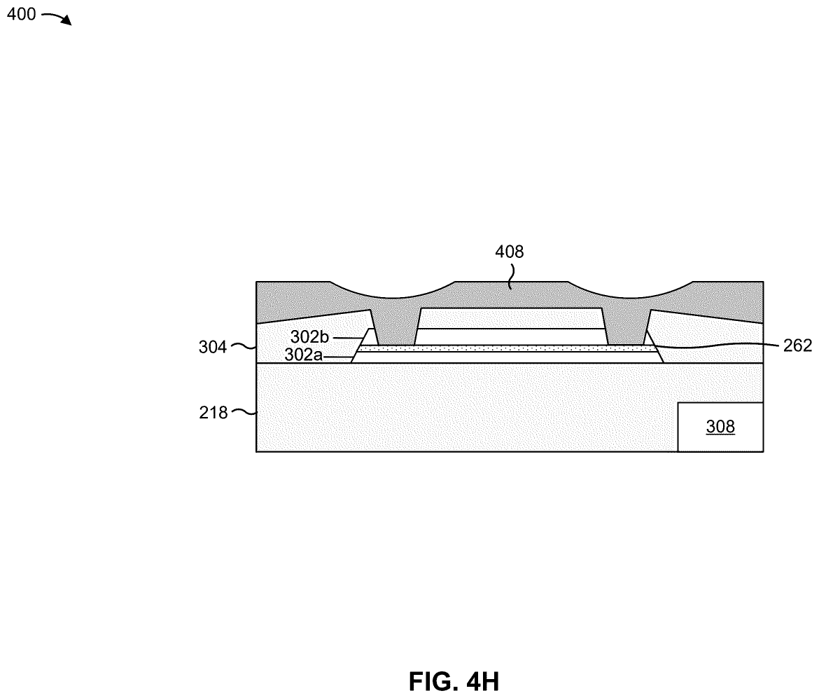

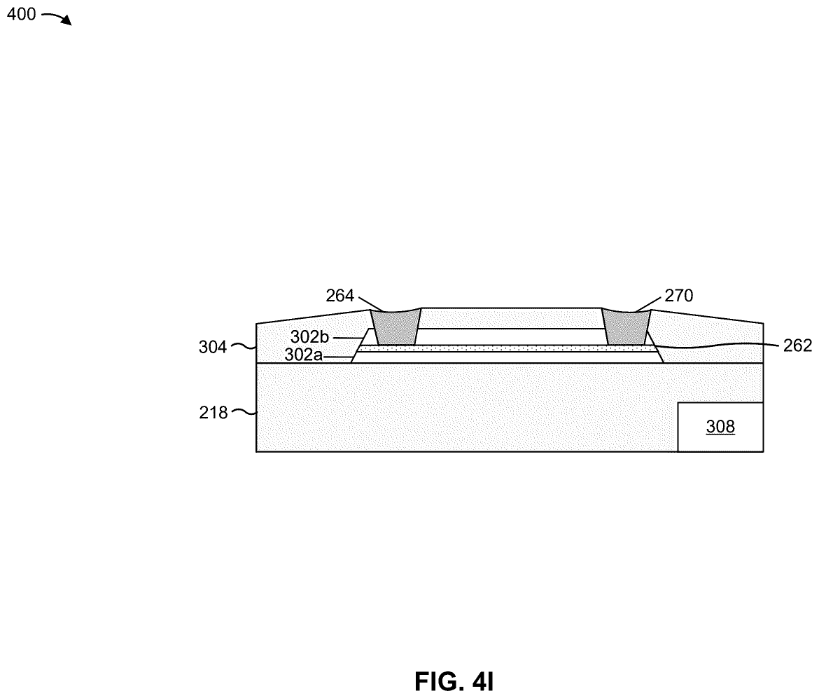

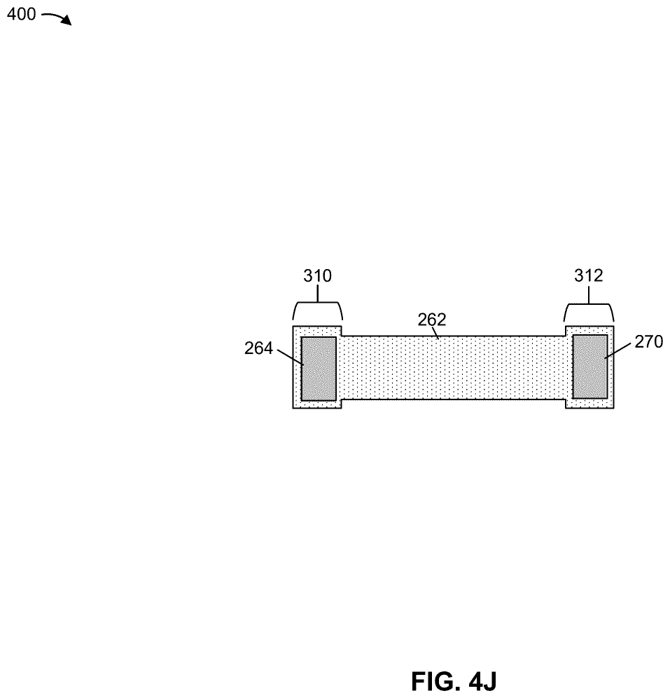

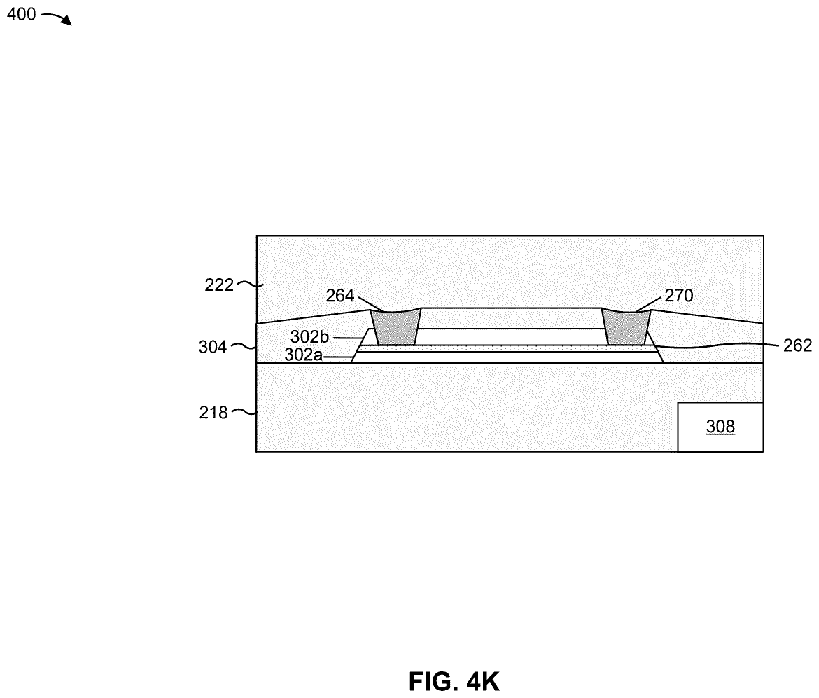

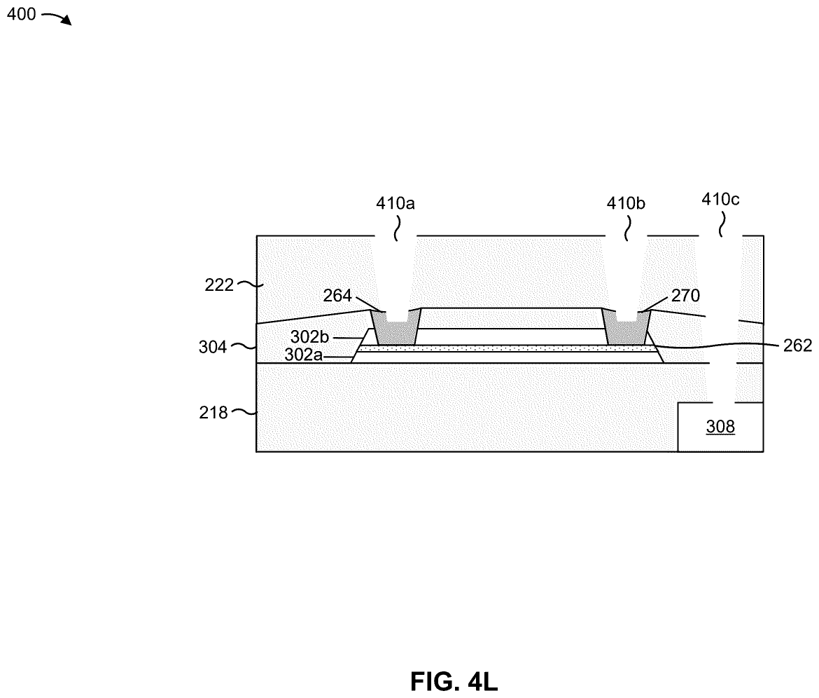

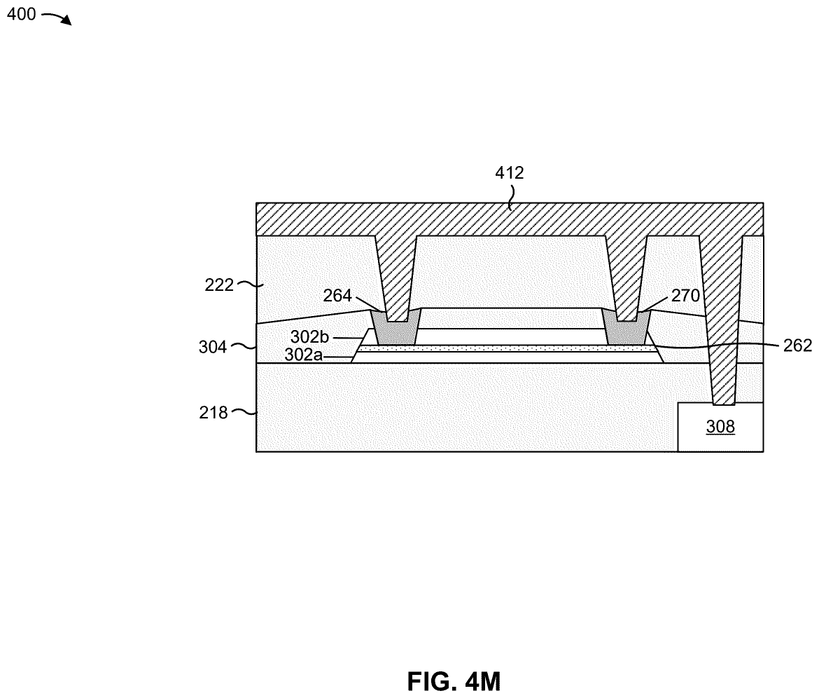

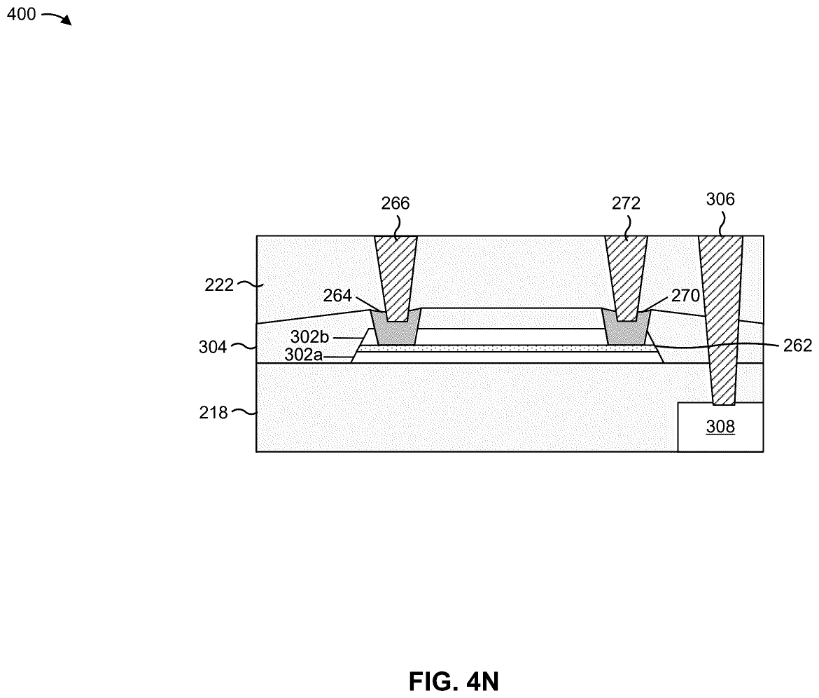

As shown in FIG. 2 and as described in connection with FIG. 3A, the TFR 262 has a taper profile. As used herein, “taper profile” refers to a three-dimensional profile where sidewalls form one or more angles with a bottom surface that are less than, or equal to, 85°. For example, a taper profile may be approximately trapezoidal, as shown in FIG. 2. Because the TFR 262 has a taper profile, the contacts 264 and 270 may be formed after deposition of a protective dielectric layer, as described in connection with FIGS. 4D-4I. Accordingly, capping layers may be omitted such that the contacts 264 and 270 physically contact the metal plugs 266 and 272, respectively, as well as the TFR 262.

As indicated above, FIG. 2 is provided as an example. Other examples may differ from what is described with regard to FIG. 2. For example, the interconnect region may further include a metal coil, as described in connection with FIG. 3A. Accordingly, the TFR 262 may be formed between a two-layer metal loop in a logic area of the semiconductor device 200.

FIG. 3A shows a cross-sectional view of an example semiconductor structure 300 including the TFR 262. As shown in FIG. 3A, the TFR 262 is between a first dielectric layer 302a (that physically contacts a first side of the TFR 262) and a dielectric layer 302b (that physically contacts a second side, opposite the first side, of the TFR 262). The dielectric layers 302a and 302b may electrically isolate the TFR 262 from surrounding structures in the interconnect region as well as protect the TFR 262 during formation and etching processes (e.g., as described in connection with FIGS. 4E-4N). In some implementations, the dielectric layers 302a and 302b are formed of undoped silicate glass (USG) and/or another type of dielectric material.

As further shown in FIG. 3A, the TFR 262 is further surrounded (at least in part) by an oxide layer 304. The oxide layer 304 further surrounds the contacts 264 and 270. The contacts 264 and 270 may be spaced apart by the oxide layer 304 such that the contacts 264 and 270 are electrically isolated to reduce the likelihood of electrical shorting between the contact 264 and the contact 270. Additionally, the oxide layer 304 may electrically isolate the contacts 264 and 270 from surrounding structures in the interconnect region as well as protect the contacts 264 and 270 during formation and etching processes (e.g., as described in connection with FIGS. 4K-4N). In some implementations, the oxide layer 304 is formed of a silicon oxide (SiOₓ). Other examples may include a protective dielectric layer (e.g., formed of a non-oxide type of dielectric material) in lieu of the oxide layer 304.

Because the TFR 262 (and the dielectric layers 302a and 302b) have a taper profile, the oxide layer 304 follows the taper profile during deposition (e.g., as described in connection with FIG. 4D. In other words, at least a portion of a top surface of the oxide layer 304 is sloped, as shown in FIG. 3A. For example, a portion of the top surface of the oxide layer 304 that is over a semiconductor stack, including the TFR 262 and the dielectric layers 302a and 302b, is farther from a top surface of the dielectric layer 218 than a portion of the top surface of the oxide layer 304 that is adjacent to the semiconductor stack.

As further shown in FIG. 3A, the metal plug 266 (e.g., formed of copper) physically contacts the contact 264, and the metal plug 272 (e.g., formed of copper) physically contacts the contact 270. The dielectric layer 222 surrounds the metal plugs 266 and 272. Therefore, the dielectric layer 222 may electrically isolate the metal plugs 266 and 272 from surrounding structures in the interconnect region. The dielectric layer 222 is substantially free of voids, as described in connection with FIG. 4K. As used herein, “substantially free of voids” refers to a layer without air gaps that exhibit a dimension (e.g., a width or a length) exceeding 0.1 micrometers (μm).

Additionally, in some implementations, the TFR 262 may be formed near a metal loop (e.g., of a logic circuit). For example, as shown in FIG. 3A, a metal plug 306 may physically contact a metal loop 308 that is in the dielectric layer 218 below the TFR 262. The metal plug 306 may extend through the dielectric layer 222 and the oxide layer 304, as well as the dielectric layer 218. Accordingly, the metal plug 306 may be associated with a higher aspect ratio (e.g., a greater width to height ratio) than the metal plugs 266 and 272.

FIG. 3B shows a top view of a cross-section of the example semiconductor structure 300 including the TFR 262. As shown in FIG. 3B, the TFR 262 has a first end portion 310 and a second end portion 312 that are wider than a middle portion 314 (even though the middle portion 314 has a larger surface area than the first end portion 310 and the second end portion 312). Accordingly, the contact 264 has a bottom surface with a smaller surface area than the first end portion 310 of the TFR 262, and the contact 270 has a bottom surface with a smaller surface area than the second end portion 312 of the TFR 262. In other words, the bottom surfaces of the contacts 264 and 270 do not overhang the TFR 262. As a result, a process window for the TFR 262 is improved because input and output signals flowing through the contacts 264 and 270 are less likely to be lost to surrounding layers.

As indicated above, FIGS. 3A-3B are provided as an example. Other examples may differ from what is described with regard to FIGS. 3A-3B.

FIGS. 4A-4N are diagrams of an example implementation 400 described herein. Example implementation 400 may be an example process for forming the example semiconductor structure 300 having a TFR with a taper profile. The semiconductor structure formed using example implementation 400 may be included in a processor, a memory, or another type of electronic device.

As shown in FIG. 4A, the example process for forming the semiconductor structure may be performed in connection with a dielectric layer 218. In some implementations, the dielectric layer 218 includes a metal loop 308 (and/or another part of a logic circuit).

As further shown in FIG. 4A, the example process may be performed in connection with a semiconductor stacking including a first dielectric layer 302a, a TFR 262, and a second dielectric layer 302b, among other examples. For example, a deposition tool 102 may form the semiconductor stack over and/or on the frontside surface of the dielectric layer 218. In some implementations, a deposition tool 102 forms the first dielectric layer 302a, the TFR 262, and the second dielectric layer 302b using a spin-coating technique, a CVD technique, a PVD technique, an ALD technique, and/or other deposition techniques.

The TFR 262 may have a depth in range from approximately 40 Ångströms (Å) to approximately 60 Å. Selecting a depth of at least 40 Å provides sufficient volume of material to function as a resistor—a smaller depth would fail to provide a measurable output signal. Selecting a depth of no more than 60 Å allows for miniaturization of the TFR 262—a larger depth would fail to result in sufficient miniaturization.

As shown in FIG. 4A, the example process may be further performed in connection with a first photoresist layer 402. For example, a deposition tool 102 may form the first photoresist layer 402 over and/or on the frontside surface of the semiconductor stack. In some implementations, a deposition tool 102 forms the first photoresist layer 402 using a spin-coating technique, a CVD technique, a PVD technique, an ALD technique, and/or other deposition techniques. Additionally, the first photoresist layer 402 may be patterned. In some implementations, an exposure tool 104 exposes the first photoresist layer 402 to a radiation source to form a pattern on the first photoresist layer 402, and a developer tool 106 develops and removes portions of the first photoresist layer 402 to expose the pattern.

As shown in FIG. 4B, the semiconductor stack may be patterned (e.g., using the first photoresist layer 402). For example, an etch tool 108 may etch a portion of the semiconductor stack. In some implementations, an etch tool 108 uses a wet etch technique, a dry etch technique, a plasma-enhanced etch technique, and/or another type of etch technique to etch the portion of the semiconductor stack. For example, an etch tool 108 may use a chemical that results in a layer of byproduct (e.g., a polymer byproduct) on sidewalls of the semiconductor structure that results in a taper profile for the semiconductor stack, as described in connection with FIG. 3A.

As further shown in FIG. 4B, the first photoresist layer 402 may be removed. For example, a photoresist removal tool 114 may remove remaining portions of the first photoresist layer 402 (e.g., using a chemical stripper, a plasma asher, and/or another technique) after an etch tool 108 etches the semiconductor stack.

In some implementations, sidewalls of the TFR 262 form one or more angles with a horizontal axis that is in a range from approximately 70° to approximately 80°. Selecting an angle of at least 70° allows for sufficient miniaturization of the TFR 262—in order to achieve a smaller angle, the TFR 262 would have to be longer in order to maintain a same height, which inhibits miniaturization, or the TFR 262 would have to have a smaller height, which reduces an output signal from the TFR 262. Selecting an angle of no more than 80° prevents void formation near the TFR 262 during deposition of the oxide layer 304—a larger angle may result in voids forming near sidewalls of the semiconductor structure. As shown in FIG. 4C, the TFR 262 has a first end portion 310 and a second end portion 312 that are wider than a middle portion 314 (even though the middle portion 314 has a larger surface area than the first end portion 310 and the second end portion 312).

As shown in FIG. 4D, an oxide layer 304 may be formed over the semiconductor stack (and the dielectric layer 218). For example, a deposition tool 102 may form the oxide layer 304 over and/or on the frontside surface of the second dielectric layer 302b (and the dielectric layer 218) as well as on sidewalls of the first dielectric layer 302a, the TFR 262, and the second dielectric layer 302b. In some implementations, a deposition tool 102 forms the oxide layer 304 using a spin-coating technique, a CVD technique, a PVD technique, an ALD technique, and/or other deposition techniques.

Because the semiconductor structure has a taper profile, the oxide layer 304 follows the taper profile during deposition. For example, as shown in FIG. 4D, a portion of a top surface of the oxide layer 304 is sloped, at least for a portion of the oxide layer 304 that physically contacts the dielectric layer 218. On the other hand, a different portion of the top surface of the oxide layer 304 is flat (e.g., for a portion of the oxide layer 304 that physically contacts the semiconductor stack).

As shown in FIG. 4E, a second photoresist layer 404 may be formed over the oxide layer 304. For example, a deposition tool 102 may form the second photoresist layer 404 over and/or on the frontside surface of the oxide layer 304. In some implementations, a deposition tool 102 forms the second photoresist layer 404 using a spin-coating technique, a CVD technique, a PVD technique, an ALD technique, and/or other deposition techniques. Additionally, the second photoresist layer 404 may be patterned. In some implementations, an exposure tool 104 exposes the second photoresist layer 404 to a radiation source to form a pattern on the second photoresist layer 404, and a developer tool 106 develops and removes portions of the second photoresist layer 404 to expose the pattern.

As shown in FIG. 4F, recesses 406a and 406b may be formed (e.g., using the second photoresist layer 404). For example, an etch tool 108 may etch a portion of the oxide layer 304. In some implementations, an etch tool 108 uses a dry etch technique, a plasma-enhanced etch technique, and/or another type of etch technique to etch the portion of the oxide layer 304. Therefore, a portion of the second dielectric layer 302b may be exposed. For example, the recess 406a exposes a portion of the second dielectric layer 302b over the first end portion 310 of the TFR 262, and the recess 406b a portion of the second dielectric layer 302b over the second end portion 312 of the TFR 262. Additionally, a portion of the second dielectric layer 302b may be etched during the same etch cycle. Therefore, the recesses 406a and 406b extend partially into the second dielectric layer 302b, as shown in FIG. 4F.

In some implementations, the etch cycle may be performed for an amount of time that satisfies a time threshold. The time threshold may be selected such that a height of the second dielectric layer 302b, between the TFR 262 and bottom surfaces of the recesses 406a and 406b, is in a range from approximately 40 Å to approximately 60 Å. Selecting a height of at least 40 Å protects the TFR 262 from damage during the etch cycle—a smaller height would not protect the TFR 262. Selecting a height of no more than 60 Å allows for exposing surfaces of the TFR 262 using a short wet etch—a larger height would result in a longer wet etch that could damage other layers.

As further shown in FIG. 4F, the second photoresist layer 404 may be removed. For example, a photoresist removal tool 114 may remove remaining portions of the second photoresist layer 404 (e.g., using a chemical stripper, a plasma asher, and/or another technique) after an etch tool 108 forms the recesses 406a and 406b.

As shown in FIG. 4G, recesses 406a and 406b may be expanded. For example, an etch tool 108 may etch a portion of the second dielectric layer 302b such that surfaces of the TFR 262 are exposed by the recesses 406a and 406b. In some implementations, an etch tool 108 uses a wet etch technique to etch the portion of the second dielectric layer 302b.

In some implementations, the etch cycle may be performed for an amount of time that satisfies a time threshold. The time threshold may be selected such that the TFR 262 is not damaged during the etch cycle. Additionally, or alternatively, the TFR 262 is resistant to an etchant used in the etch cycle. For example, the TFR 262 may be a chromium-based material, as described in connection with FIG. 3A, and the etchant may be hydrofluoric acid (HF). As a result, the TFR 262 resists damage during the etch cycle.

As shown in FIG. 4H, the recesses 406a and 406b may be filled with metal nitride 408 (and/or another type of conductive material). For example, a deposition tool 102 may deposit the metal nitride 408 using a spin-coating technique, a CVD technique, a PVD technique, an ALD technique, and/or other deposition techniques. In some implementations, the metal nitride 408 may overflow the recesses 406a and 406b. Therefore, as shown in FIG. 4I, excess metal nitride outside the recesses 406a and 406b may be removed to form the contacts 264 and 270. For example, a planarization tool 110 removes excess metal nitride using a CMP technique. As further shown in FIG. 4I, the CMP technique may result in minor “dishing” of the contacts 264 and 270. For example, inner portions of the contacts 264 and 270 may rest lower in the recesses 406a and 406b, respectively, as compared with outer portions of the contacts 264 and 270.

As shown in FIG. 4J, the contact 264 has a bottom surface with a smaller surface area than the first end portion 310 of the TFR 262, and the contact 270 has a bottom surface with a smaller surface area than the second end portion 312 of the TFR 262. In other words, the bottom surfaces of the contacts 264 and 270 do not overhang the TFR 262. As a result, a process window for the TFR 262 is improved because input and output signals flowing through the contacts 264 and 270 are less likely to be lost to surrounding layers.

As shown in FIG. 4K, an IMD 222 may be formed over the oxide layer 304 (and the contacts 264 and 270). For example, a deposition tool 102 may form the IMD 222 over and/or on the frontside surface of the oxide layer 304. In some implementations, a deposition tool 102 forms the IMD 222 using a spin-coating technique, a CVD technique, a PVD technique, an ALD technique, and/or other deposition techniques. Because the contacts 264 and 270 are protected by the oxide layer 304 during formation of the IMD 222, the IMD 222 is substantially free of voids, as described in connection with FIG. 3A.

As shown in FIG. 4L, recesses 410a and 410b may be formed through the IMD 222 to expose the contacts 264 and 270. Additionally, recess 410c may be formed through the IMD 222, the oxide layer 304, and the dielectric layer 218 to expose the metal loop 308. In some implementations, a deposition tool 102 may form a photoresist layer on the IMD 222, an exposure tool 104 may expose the photoresist layer to a radiation source to pattern the photoresist layer, a developer tool 106 may develop and remove portions of the photoresist layer to expose the pattern, and an etch tool 108 may etch through portions of the IMD 222 to form the recesses 410a and 410b and through portions of the IMD 222, the oxide layer 304, and the dielectric layer 218 to form the recess 410c. In some implementations, as shown in FIG. 4L, the contacts 264 and 270 may also be partially etched (such that the recesses 410a and 410b partially extend into the contacts 264 and 270). Additionally, or alternatively, as shown in FIG. 4L, the metal loop 308 may also be partially etched (such that the recess 410c partially extends into the metal loop 308). In some implementations, a photoresist removal tool 114 removes the remaining portions of the photoresist layer (e.g., using a chemical stripper and/or another technique) after the etch tool 108 forms the recesses 410a, 410b, and 410c.

As shown in FIG. 4M, the recesses 410a, 410b, and 410c may be filled with copper 412 (and/or another type of conductive material). For example, a deposition tool 102 may deposit the copper 412 using a spin-coating technique, a CVD technique, a PVD technique, an ALD technique, and/or other deposition techniques. In some implementations, the copper 412 may overflow the recesses 410a, 410b, and 410c. Therefore, as shown in FIG. 4N, excess copper outside the recesses 410a, 410b, and 410c may be removed to form the metal plugs 266, 272, and 306. For example, a planarization tool 110 removes excess copper using a CMP technique.

As indicated above, FIGS. 4A-4N are provided as an example. Other examples may differ from what is described with regard to FIGS. 4A-4N. For example, the recess 410c may be formed in a separate etch cycle as compared with the recesses 410a and 410b.

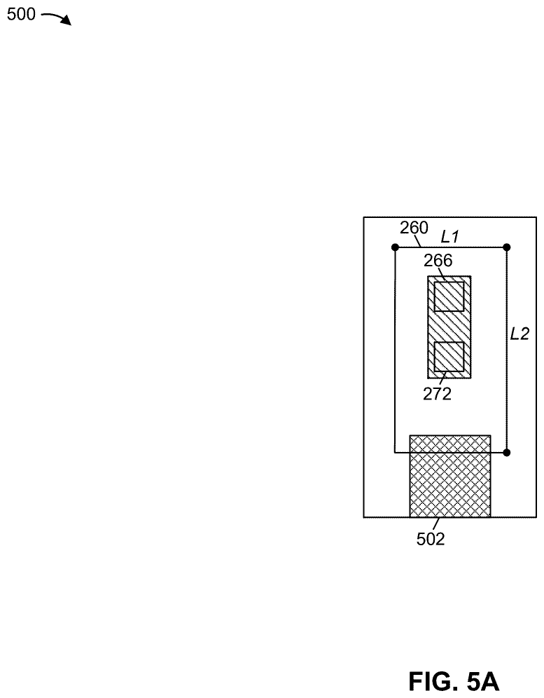

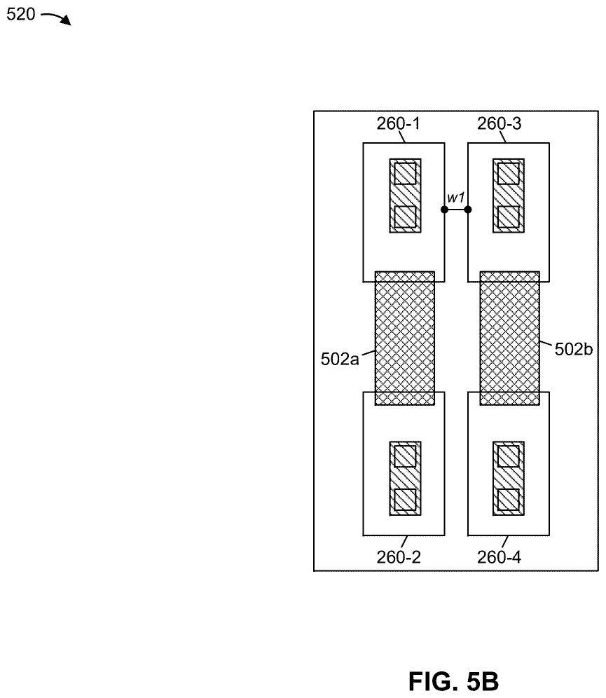

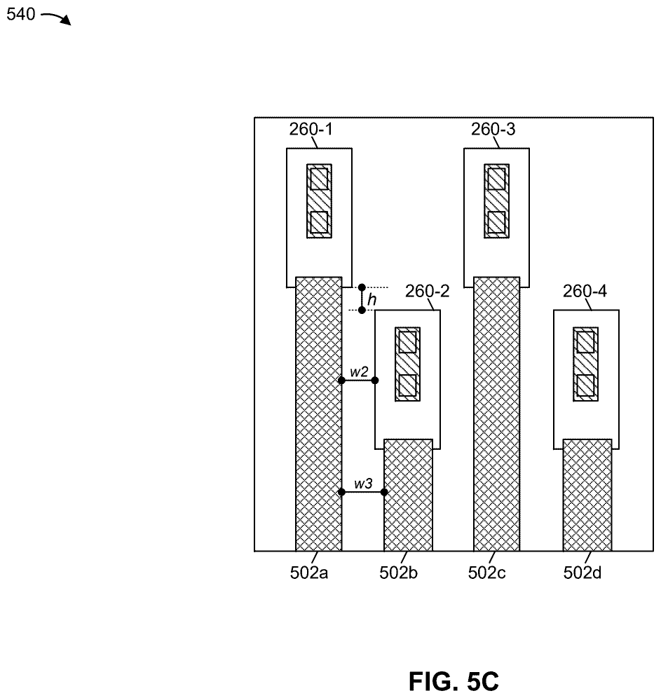

FIG. 5A shows an example semiconductor layout 500 including a TFR as described herein. As shown in FIG. 5A, the metal plugs 266 and 272 of a resistor structure 260 may be reduced in size because there is no lateral etching of contacts below the metal plugs during formation. In other words, the metal plugs 266 and 272 may be formed to a smaller size because a landing area for the metal plugs 266 and 272 (on the contacts 264 and 270, not shown in FIG. 5A) is not modified by lateral etching. Additionally, a TFR of the resistor structure 260 is reduced in size because the TFR is not damaged during CMP. In other words, the TFR may be formed to a smaller size because the size of the TFR is not reduced during formation of the contacts 264 and 270 (not shown in FIG. 5A) and the metal plugs 266 and 272. Accordingly, a size of a landing area associated with the resistor structure 260 is reduced. For example, as shown in FIG. 5A, a width (e.g., represented by L1) of the landing area may be reduced by up to 30% as compared with extant resistor structures. Similarly, a length (e.g., represented by L2 in FIG. 5A) of the landing area may be reduced by up to 15% as compared with extant resistor structures. As a result, the landing area may be reduced by up to 40% as compared with extant resistor structures. Therefore, additional components in the interconnect region (e.g., component 502) may be formed with increased density relative to the resistor structure 260.

FIG. 5B shows an example semiconductor layout 520. The example semiconductor layout 520 is similar to the example semiconductor layout 500 but includes four resistor structures 260-1, 260-2, 260-3, and 260-4. A lateral spacing between adjacent resistor structures (e.g., represented by w1 in FIG. 5B between resistor structures 260-1 and 260-3) may be in a range from approximately 0.2 μm to approximately 0.6 μm. Selecting a lateral spacing of at least 0.2 μm electrically isolates the adjacent resistor structures—a smaller lateral spacing would result in measurement errors caused by electrical interference. Selecting a lateral spacing of no more than 0.6 μm allows additional components in the interconnect region (e.g., components 502a and 502b) to be formed with increased density relative to the adjacent resistor structures—a larger lateral spacing would fail to result in sufficient miniaturization.

FIG. 5C shows an example semiconductor layout 540. The example semiconductor layout 520 is similar to the example semiconductor layout 500 but includes four resistor structures 260-1, 260-2, 260-3, and 260-4. A lateral spacing between adjacent resistor structures (e.g., represented by h in FIG. 5C between resistor structures 260-1 and 260-2) may be in a range from approximately 0.2 μm to approximately 0.6 μm. Selecting a lateral spacing of at least 0.2 μm electrically isolates the adjacent resistor structures—a smaller lateral spacing would result in measurement errors caused by electrical interference. Selecting a lateral spacing of no more than 0.6 μm allows for additional resistor structures (e.g., resistor structures 260-3 and 260-4) to be formed with increased density—a larger lateral spacing would fail to result in sufficient miniaturization.

As further shown in FIG. 5C, a lateral spacing between a resistor structure and an additional component (e.g., represented by w2 in FIG. 5C between resistor structure 260-2 and component 502a) may be in a range from approximately 0.5 μm to approximately 0.9 μm. Selecting a lateral spacing of at least 0.5 μm electrically isolates the resistor structure from the additional component—a smaller lateral spacing would result in measurement errors caused by electrical interference. Selecting a lateral spacing of no more than 0.9 μm allows additional components in the interconnect region (e.g., components 502b, 502c, and 502d) to be formed with increased density—a larger lateral spacing would fail to result in sufficient miniaturization. Similarly, a lateral spacing between adjacent components (e.g., represented by w3 in FIG. 5C between components 502a and 502b) may be in a range from approximately 0.7 μm to approximately 1.1 μm. Selecting a lateral spacing of at least 0.7 μm electrically isolates the adjacent components—a smaller lateral spacing would result in errors (e.g., in logic errors) caused by electrical interference. Selecting a lateral spacing of no more than 1.1 μm allows additional components in the interconnect region (e.g., components 502c and 502d) to be formed with increased density—a larger lateral spacing would fail to result in sufficient miniaturization.

As indicated above, FIGS. 5A-5C are provided as examples. Other examples may differ from what is described with regard to FIGS. 5A-5C.

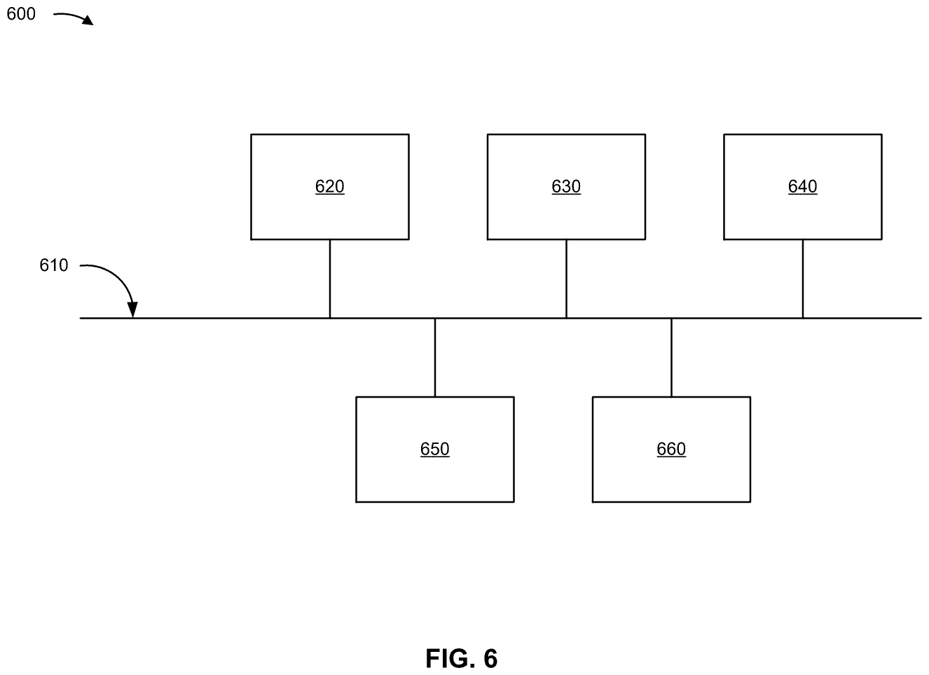

FIG. 6 is a diagram of example components of a device 600 described herein. In some implementations, one or more of the semiconductor processing tools 102-116 and/or the wafer/die transport tool 118 may include one or more devices 600 and/or one or more components of device 600. As shown in FIG. 6, device 600 may include a bus 610, a processor 620, a memory 630, an input component 640, an output component 650, and a communication component 660.

Bus 610 may include one or more components that enable wired and/or wireless communication among the components of device 600. Bus 610 may couple together two or more components of FIG. 6, such as via operative coupling, communicative coupling, electronic coupling, and/or electric coupling. Processor 620 may include a central processing unit, a graphics processing unit, a microprocessor, a controller, a microcontroller, a digital signal processor, a field-programmable gate array, an application-specific integrated circuit, and/or another type of processing component. Processor 620 is implemented in hardware, firmware, or a combination of hardware, software, and firmware. In some implementations, processor 620 may include one or more processors capable of being programmed to perform one or more operations or processes described elsewhere herein.

Memory 630 may include volatile and/or nonvolatile memory. For example, memory 630 may include random access memory (RAM), read only memory (ROM), a hard disk drive, and/or another type of memory (e.g., a flash memory, a magnetic memory, and/or an optical memory). Memory 630 may include internal memory (e.g., RAM, ROM, or a hard disk drive) and/or removable memory (e.g., removable via a universal serial bus connection). Memory 630 may be a non-transitory computer-readable medium. Memory 630 stores information, instructions, and/or software (e.g., one or more software applications) related to the operation of device 600. In some implementations, memory 630 may include one or more memories that are coupled to one or more processors (e.g., processor 620), such as via bus 610.

Input component 640 enables device 600 to receive input, such as user input and/or sensed input. For example, input component 640 may include a touch screen, a keyboard, a keypad, a mouse, a button, a microphone, a switch, a sensor, a global positioning system sensor, an accelerometer, a gyroscope, and/or an actuator. Output component 650 enables device 600 to provide output, such as via a display, a speaker, and/or a light-emitting diode. Communication component 660 enables device 600 to communicate with other devices via a wired connection and/or a wireless connection. For example, communication component 660 may include a receiver, a transmitter, a transceiver, a modem, a network interface card, and/or an antenna.

Device 600 may perform one or more operations or processes described herein. For example, a non-transitory computer-readable medium (e.g., memory 630) may store a set of instructions (e.g., one or more instructions or code) for execution by processor 620. Processor 620 may execute the set of instructions to perform one or more operations or processes described herein. In some implementations, execution of the set of instructions, by one or more processors 620, causes the one or more processors 620 and/or the device 600 to perform one or more operations or processes described herein. In some implementations, hardwired circuitry is used instead of or in combination with the instructions to perform one or more operations or processes described herein. Additionally, or alternatively, processor 620 may be configured to perform one or more operations or processes described herein. Thus, implementations described herein are not limited to any specific combination of hardware circuitry and software.

The number and arrangement of components shown in FIG. 6 are provided as an example. Device 600 may include additional components, fewer components, different components, or differently arranged components than those shown in FIG. 6. Additionally, or alternatively, a set of components (e.g., one or more components) of device 600 may perform one or more functions described as being performed by another set of components of device 600.

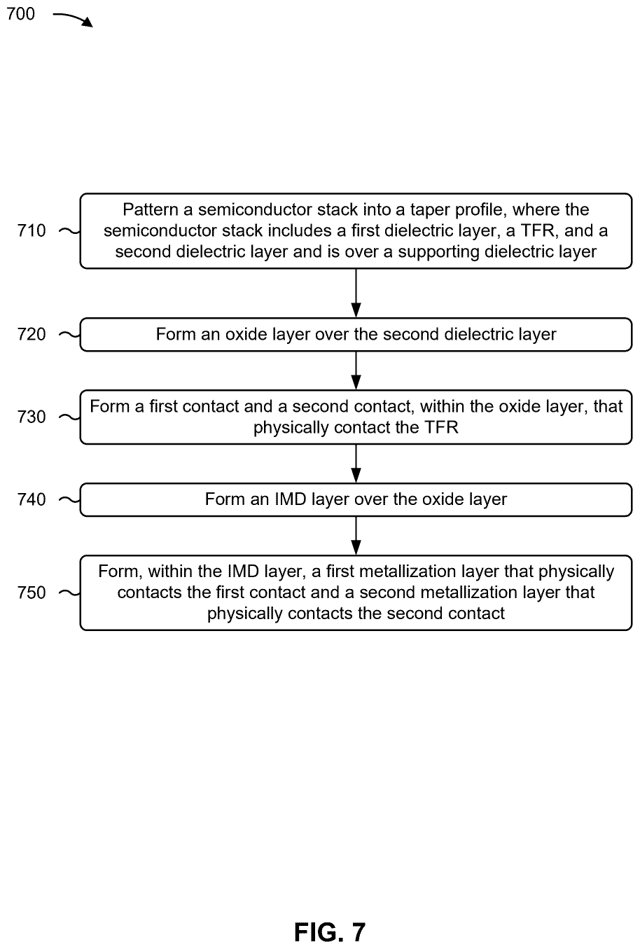

FIG. 7 is a flowchart of an example process 700 associated with forming semiconductor structures described herein. In some implementations, one or more process blocks of FIG. 7 are performed using one or more semiconductor processing tools (e.g., one or more of the semiconductor processing tools 102-116). Additionally, or alternatively, one or more process blocks of FIG. 7 may be performed using one or more components of device 600, such as processor 620, memory 630, input component 640, output component 650, and/or communication component 660.

As shown in FIG. 7, process 700 may include patterning a semiconductor stack into a taper profile, where the semiconductor stack includes a first dielectric layer, a TFR, and a second dielectric layer and is over a supporting dielectric layer (block 710). For example, one or more of the semiconductor processing tools 102-116 may be used to pattern a semiconductor stack into a taper profile, where the semiconductor stack includes a first dielectric layer 302a, a TFR 262, and a second dielectric layer 302b and is over a supporting dielectric layer 218, as described herein.

As further shown in FIG. 7, process 700 may include forming an oxide layer over the second dielectric layer (block 720). For example, one or more of the semiconductor processing tools 102-116 may be used to form an oxide layer 304 over the second dielectric layer 302b, as described herein.

As further shown in FIG. 7, process 700 may include forming a first contact and a second contact, within the oxide layer, that physically contact the TFR (block 730). For example, one or more of the semiconductor processing tools 102-116 may be used to form a first contact 264 and a second contact 270, within the oxide layer 304, that physically contact the TFR 262, as described herein.

As further shown in FIG. 7, process 700 may include forming an IMD layer over the oxide layer (block 740). For example, one or more of the semiconductor processing tools 102-116 may be used to form an IMD layer 222 over the oxide layer 304, as described herein.

As further shown in FIG. 7, process 700 may include forming, within the IMD layer, a first metal plug that physically contacts the first contact and a second metal plug that physically contacts the second contact (block 750). For example, one or more of the semiconductor processing tools 102-116 may be used to form, within the IMD layer 222, a first metal plug 266 that physically contacts the first contact 264 and a second metal plug 272 that physically contacts the second contact 270, as described herein.

Process 700 may include additional implementations, such as any single implementation or any combination of implementations described below and/or in connection with one or more other processes described elsewhere herein.

In a first implementation, a first portion of a top surface of the oxide layer 304, over the semiconductor stack, is farther from a top surface of the supporting dielectric layer 218 than a second portion of the top surface of the oxide layer 304, adjacent to the semiconductor stack.

In a second implementation, alone or in combination with the first implementation, the TFR 262 includes a first end portion 310 and a second end portion 312 that are wider than a middle portion 314, the first contact 264 has a bottom surface with a smaller surface area than the first end portion 310 of the TFR 262, and the second contact 270 has a bottom surface with a smaller surface area than the second end portion 312 of the TFR 262.

In a third implementation, alone or in combination with one or more of the first and second implementations, the IMD layer 222 is substantially free of voids.

In a fourth implementation, alone or in combination with one or more of the first through third implementations, patterning the semiconductor stack include forming a first photoresist layer 402 over the semiconductor stack and patterning the semiconductor stack into the taper profile using the first photoresist layer 402. Additionally, process 700 may include removing the first photoresist layer 402 after patterning the semiconductor stack.

In a fifth implementation, alone or in combination with one or more of the first through fourth implementations, forming the first contact 264 and the second contact 270 includes forming a second photoresist layer 404 over the oxide layer 304, forming a first recess 406a and a second recess 406b in the oxide layer 304 using the second photoresist layer 404, expanding the first recess 406a and the second recess 406b to expose a portion of the TFR 262, and forming the first contact 264 in the first recess 406a and the second contact 270 in the second recess 406b. Forming the first recess 406a and the second recess 406b may include performing at least one dry etch cycle, and expanding the first recess 406a and the second recess 406b may include performing at least one wet etch cycle. The TFR 262 may be resistant to an etchant used in the at least one wet etch cycle. Additionally, process 700 may include removing the second photoresist layer 404 after forming the first recess 406a and the second recess 406b.

In a sixth implementation, alone or in combination with one or more of the first through fifth implementations, forming the first metal plug 266 and the second metal plug 272 includes forming a third recess 410a and a fourth recess 410b in the IMD layer 222 and forming the first metal plug 266 in the third recess 410a and the second metal plug 272 in the fourth recess 410b.

In a seventh implementation, alone or in combination with one or more of the first through sixth implementations, forming the first contact 264 and the second contact 270 includes depositing a metal nitride 408 and performing CMP to remove excess metal nitride.

In an eighth implementation, alone or in combination with one or more of the first through seventh implementations, forming the first metal plug 266 and the second metal plug 272 includes depositing copper 412 and performing CMP to remove excess copper.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

In this way, a TFR is formed with a taper profile, which allows for patterning of contacts after deposition of an oxide layer. Therefore, the contacts are not laterally etched, and thus there is no overhang of capping layers to result in voids and/or seams when an IMD is formed around the contacts. As a result, a process window for the TFR is improved because the contacts are not reduced by lateral etching. Furthermore, with no lateral etching of the contacts, voids and/or seams are reduced (or even eliminated) when the IMD is formed around the contacts. Fewer voids and/or seams improves the structural integrity of an interconnect region that includes the TFR and prevents damage to the TFR during CMP. Therefore, measurement accuracy for the TFR is increased. Moreover, fewer voids and/or seams result in increased semiconductor device yield in that fewer semiconductor devices are formed with non-functional components in the interconnect region and thus fewer semiconductor devices are scrapped.

As described in greater detail above, some implementations described herein provide a semiconductor structure. The semiconductor structure includes a thin film resistor (TFR) with a taper profile. The semiconductor structure includes a first contact physically contacting a first portion of the TFR. The semiconductor structure includes a second contact physically contacting a second portion of the TFR.

As described in greater detail above, some implementations described herein provide a method. The method includes forming a first photoresist layer over a semiconductor stack including a first dielectric layer, a thin film resistor (TFR), and a second dielectric layer. The method includes patterning the semiconductor stack into a taper profile using the first photoresist layer. The method includes forming an oxide layer over the second dielectric layer. The method includes forming a second photoresist layer over the oxide layer. The method includes forming a first recess and a second recess in the oxide layer using the second photoresist layer. The method includes expanding the first recess and the second recess to expose a portion of the TFR. The method includes forming a first contact in the first recess and a second contact in the second recess. The method includes forming an inter-metal dielectric (IMD) layer over the oxide layer. The method includes forming a third recess and a fourth recess in the IMD layer. The method includes forming a first metal plug in the third recess and a second metal plug in the fourth recess.

As described in greater detail above, some implementations described herein provide a method. The method includes patterning a semiconductor stack into a taper profile, wherein the semiconductor stack includes a first dielectric layer, a thin film resistor (TFR), and a second dielectric layer and is over a supporting dielectric layer. The method includes forming an oxide layer over the second dielectric layer. The method includes forming a first contact and a second contact, within the oxide layer, that physically contact the TFR. The method includes forming an inter-metal dielectric (IMD) layer over the oxide layer. The method includes forming a third recess and a fourth recess in the IMD layer. The method includes forming, within the IMD layer, a first metal plug that physically contacts the first contact and a second metal plug that physically contacts the second contact.

As used herein, “satisfying a threshold” may, depending on the context, refer to a value being greater than the threshold, greater than or equal to the threshold, less than the threshold, less than or equal to the threshold, equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a thin film resistor (TFR) with a taper profile;
a first contact physically contacting a first portion of the TFR; and
a second contact physically contacting a second portion of the TFR.

2. The semiconductor structure of claim 1, further comprising:
a first dielectric layer physically contacting a first side of the TFR; and
a second dielectric layer physically contacting a second side, opposite the first side, of the TFR.

3. The semiconductor structure of claim 2, wherein the first dielectric layer and the second dielectric layer comprise undoped silicate glass.

4. The semiconductor structure of claim 2, further comprising:
an oxide layer over the second dielectric layer and surrounding the first contact and the second contact.

5. The semiconductor structure of claim 4, further comprising:
an inter-metal dielectric (IMD) layer over the oxide layer.

6. The semiconductor structure of claim 5, wherein the IMD layer is substantially free of voids.

7. The semiconductor structure of claim 1, further comprising:
a first metal plug physically contacting the first contact; and
a second metal plug physically contacting the second contact.

8. The semiconductor structure of claim 1, wherein sidewalls of the TFR form one or more angles with a horizontal axis in a range from approximately 70 degrees to approximately 80 degrees.

9. The semiconductor structure of claim 1, wherein the TFR is included in an interconnect region of a semiconductor device.

10. A method, comprising:
forming a first photoresist layer over a semiconductor stack including a first dielectric layer, a thin film resistor (TFR), and a second dielectric layer;
patterning the semiconductor stack into a taper profile using the first photoresist layer;
forming an oxide layer over the second dielectric layer;
forming a second photoresist layer over the oxide layer;
forming a first recess and a second recess in the oxide layer using the second photoresist layer;
expanding the first recess and the second recess to expose a portion of the TFR;
forming a first contact in the first recess and a second contact in the second recess;
forming an inter-metal dielectric (IMD) layer over the oxide layer;
forming a third recess and a fourth recess in the IMD layer; and
forming a first metal plug in the third recess and a second metal plug in the fourth recess.

11. The method of claim 10, further comprising:
removing the first photoresist layer after patterning the semiconductor stack.

12. The method of claim 10, further comprising:
removing the second photoresist layer after forming the first recess and the second recess.

13. The method of claim 10, wherein:
forming the first recess and the second recess comprises performing at least one dry etch cycle; and
expanding the first recess and the second recess comprises performing at least one wet etch cycle.

14. The method of claim 13, where the TFR is resistant to an etchant used in the at least one wet etch cycle.

15. The method of claim 10, wherein forming the first contact and the second contact comprises:
depositing a metal nitride in the first recess and the second recess, wherein the metal nitride overflows the first recess and the second recess; and
performing chemical mechanical planarization to remove excess metal nitride outside the first recess and the second recess.

16. The method of claim 10, wherein forming the first metal plug and the second metal plug comprises:
depositing copper in the third recess and the fourth recess, wherein the copper overflows the third recess and the fourth recess; and
performing chemical mechanical planarization to remove excess copper outside the third recess and the fourth recess.

17. A method, comprising:
patterning a semiconductor stack into a taper profile, wherein the semiconductor stack includes a first dielectric layer, a thin film resistor (TFR), and a second dielectric layer and is over a supporting dielectric layer;
forming an oxide layer over the second dielectric layer;
forming a first contact and a second contact, within the oxide layer, that physically contact the TFR;
forming an inter-metal dielectric (IMD) layer over the oxide layer; and
forming, within the IMD layer, a first metal plug that physically contacts the first contact and a second metal plug that physically contacts the second contact.

18. The method of claim 17, wherein a first portion of a top surface of the oxide layer, over the semiconductor stack, is farther from a top surface of the supporting dielectric layer than a second portion of the top surface of the oxide layer, adjacent to the semiconductor stack.

19. The method of claim 17, wherein the TFR includes a first end portion and a second end portion that are wider than a middle portion, the first contact has a bottom surface with a smaller surface area than the first end portion of the TFR, and the second contact has a bottom surface with a smaller surface area than the second end portion of the TFR.

20. The method of claim 17, wherein the IMD layer is substantially free of voids.
